(19) United States
(12) Patent Application Publication
(10) Pub. No.: US 2026/0194743 A1
(43) Pub. Date: Jul. 9, 2026

(54) BEAM STEERING DEVICE, LASER SYSTEM, BEAM STEERING METHOD, AND ELECTRONIC DEVICE MANUFACTURING METHOD

(71) Applicant: Gigaphoton Inc., Tochigi (JP)

(72) Inventors: Kohei KUSAYANAGI, Tochigi (JP); Hirotaka MIYAMOTO, Tochigi (JP)

(73) Assignee: Gigaphoton Inc., Tochigi (JP)

(21) Appl. No.: 19/409,108

(22) Filed: Dec. 4, 2025

(30) Foreign Application Priority Data
Jan. 9, 2025 (JP) 2025-003265

(51) Int. Cl. G02B 26/08; G03F 7/00; H01S 3/00

(52) U.S. Cl. CPC G02B 26/0816; G03F 7/70025; G03F 7/70041; G03F 7/70358; G03F 7/70825; G03F 7/7085; H01S 3/0057; H01S 3/0071

(57) ABSTRACT

A beam steering device includes a first mirror configured to reflect, in a second direction, laser light incident thereon in a first direction; a second mirror configured to reflect, in a third direction, the laser light reflected by the first mirror; a first stage configured to integrally move the first mirror and the second mirror in a direction parallel to the first direction; a second stage arranged on the first stage and configured to move the second mirror in a direction parallel to the second direction; and a holder arranged on the second stage and configured to adjust an orientation of a reflection surface of the second mirror.

### CROSS-REFERENCE TO RELATED APPLICATIONS

The present application claims the benefit of Japanese Patent Application No. 2025-003265, filed on Jan. 9, 2025, the entire contents of which are hereby incorporated by reference.

### BACKGROUND

### 1. Technical Field

The present disclosure relates to a beam steering device, a laser system, a beam steering method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

Since excimer laser light output from a KrF excimer laser device or an ArF excimer laser device has a pulse width of several 10 ns and a wavelength thereof is short as about 248 nm or 193 nm, excimer laser light is sometimes used for direct processing of a polymer material, a glass material, or the like. Chemical bonds in polymeric materials can be broken by excimer laser light having a photon energy higher than the bond energy. Therefore, it is known that non-heating processing of polymeric materials is possible with excimer laser light, and that the processing shape is beautiful. Further, it is known that, since glass, ceramics, and the like have high absorptance with respect to excimer laser light, even a material that is difficult to be processed with visible and infrared laser light can be processed with excimer laser light.

### LIST OF DOCUMENTS

### Patent Documents

Patent Document 1: US Patent Application Publication No. 2023/061530

Patent Document 2: Japanese Patent Application Publication No. 2008-277616

### SUMMARY

A beam steering device according to an aspect of the present disclosure includes a first mirror configured to reflect, in a second direction, laser light incident thereon in a first direction; a second mirror configured to reflect, in a third direction, the laser light reflected by the first mirror; a first stage configured to integrally move the first mirror and the second mirror in a direction parallel to the first direction; a second stage arranged on the first stage and configured to move the second mirror in a direction parallel to the second direction; and a holder arranged on the second stage and configured to adjust an orientation of a reflection surface of the second mirror.

A beam steering method using a beam steering device for laser light according to an aspect of the present disclosure includes moving a first mirror and a second mirror in a direction parallel to a first direction by a same amount, moving the second mirror in a direction parallel to a second direction, and adjusting an orientation of a reflection surface of the second mirror. Here, the beam steering device includes the first mirror configured to reflect, in the second direction, the laser light incident thereon in the first direction; and the second mirror configured to reflect, in a third direction, the laser light reflected by the first mirror.

An electronic device manufacturing method according to an aspect of the present disclosure includes generating laser light using a laser system, outputting the laser light to an exposure apparatus, and exposing a photosensitive substrate to the laser light in the exposure apparatus to manufacture an electronic device. Here, the laser system includes a laser oscillator, a pulse extension device including a delay optical path that allows a portion of the laser light output from the laser oscillator to pass therethrough, and a beam steering device arranged on an optical path of the laser light between the laser oscillator and the pulse extension device. The beam steering device includes a first mirror configured to reflect, in a second direction, the laser light incident thereon in a first direction; a second mirror configured to reflect, in a third direction, the laser light reflected by the first mirror; a first stage configured to integrally move the first mirror and the second mirror in a direction parallel to the first direction; a second stage arranged on the first stage and configured to move the second mirror in a direction parallel to the second direction; and a holder arranged on the second stage and configured to adjust an orientation of a reflection surface of the second mirror.

### BRIEF DESCRIPTION OF THE DRAWINGS

Embodiments of the present disclosure will be described below merely as examples with reference to the accompanying drawings.

FIG. 1 shows the configuration of a laser system of a comparative example.

FIG. 2 shows the configuration of a pulse extension device of the comparative example viewed in a −V direction.

FIG. 3 is a perspective view of the pulse extension device of the comparative example.

FIG. 4 shows the configuration of a beam steering device according to a first example of a first embodiment.

FIG. 5 shows a first stage shown in FIG. 4.

FIG. 6 shows the configuration of the beam steering device according to a second example of the first embodiment.

FIG. 7 shows the configuration of the beam steering device according to a third example of the first embodiment.

FIG. 8 shows the first stage shown in FIG. 7.

FIG. 9 is a flowchart of optical axis adjustment in a second embodiment.

FIG. 10 is a flowchart of a first example of optical axis adjustment of input light in the second embodiment.

FIG. 11 is a flowchart of a first example of optical axis adjustment of output light in the second embodiment.

FIG. 12 is a flowchart of a second example of optical axis adjustment of the input light in the second embodiment.

FIG. 13 is a flowchart of a second example of optical axis adjustment of the output light in the second embodiment.

FIG. 14 shows the configuration of an exposure system.

### DESCRIPTION OF EMBODIMENTS

### Contents

1. Comparative example
1.1 Configuration of laser system 100
1.2 Operation of laser system 100
1.3 Pulse extension device 5

2. Problem of comparative example

3. Beam steering device in which two mirrors are integrally moved
3.1 Beam steering device 60c
3.2 Beam steering device 60d
3.3 Beam steering device 60e
3.4 Effect

4. Beam steering method
4.1 Main flow
4.2 First example of optical axis adjustment of input light
4.3 First example of optical axis adjustment of output light
4.4 Second example of optical axis adjustment of input light
4.5 Second example of optical axis adjustment of output light
4.6 Effect

5. Others
5.1 Electronic device manufacturing method
5.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration of Laser System 100

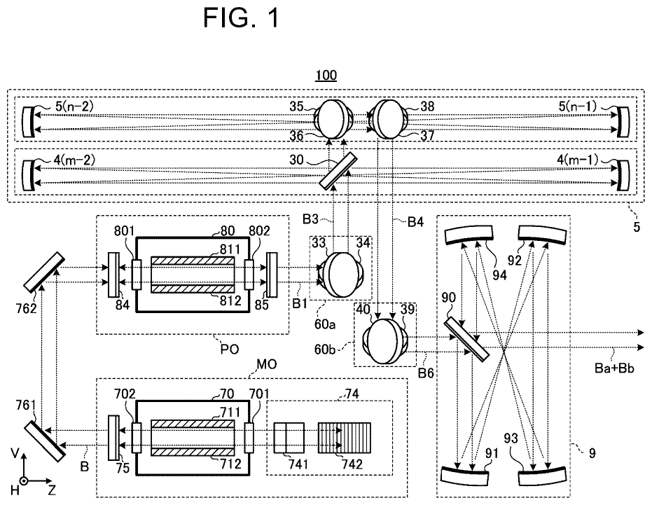

FIG. 1 shows the configuration of a laser system 100 of a comparative example. The comparative example of the present disclosure is an example recognized by the applicant as known only by the applicant, and is not a publicly known example admitted by the applicant. The laser system 100 includes a laser oscillator MO, a laser amplifier PO, beam steering devices 60a, 60b, and pulse extension devices 5, 9.

The laser oscillator MO includes a laser chamber 70, a line narrowing module 74, and an output coupling mirror 75.

The laser chamber 70 is arranged on the optical path of a laser resonator configured by the line narrowing module 74 and the output coupling mirror 75. The laser chamber 70 is provided with two windows 701, 702. The laser chamber 70 accommodates discharge electrodes 711, 712. The discharge electrodes 711, 712 are connected to a pulse power source (not shown). The laser chamber 70 contains a laser gas as a laser medium. The laser gas includes, for example, an argon gas, a fluorine gas, and a neon gas. Alternatively, the laser gas includes, for example, a krypton gas, a fluorine gas, and a neon gas.

The line narrowing module 74 includes wavelength selection elements such as a prism 741 and a grating 742. The output coupling mirror 75 is configured by a partial reflection mirror.

High reflection mirrors 761, 762 are arranged in this order on the optical path of laser light B output from the output coupling mirror 75.

The laser amplifier PO includes a laser chamber 80, a rear mirror 84, and an output coupling mirror 85. The laser chamber 80, the output coupling mirror 85, and windows 801, 802 and discharge electrodes 811, 812 associated with the laser chamber 80 are similar to the corresponding components in the laser oscillator MO.

The rear mirror 84 is arranged on the optical path of the laser light B reflected by the high reflection mirror 762. The rear mirror 84 is configured by a partial reflection mirror. The rear mirror 84 and the output coupling mirror 85 configure a laser resonator.

The travel direction of laser light B1 output from the laser amplifier PO is represented by a Z direction. A direction in which the discharge electrodes 711, 712 face each other is represented by a V direction or a −V direction. The Z direction and the V direction are perpendicular to each other, and the direction perpendicular to both of them is represented by an H direction or a −H direction. In FIG. 1, the configuration of the laser system 100 is shown as viewed in the −H direction.

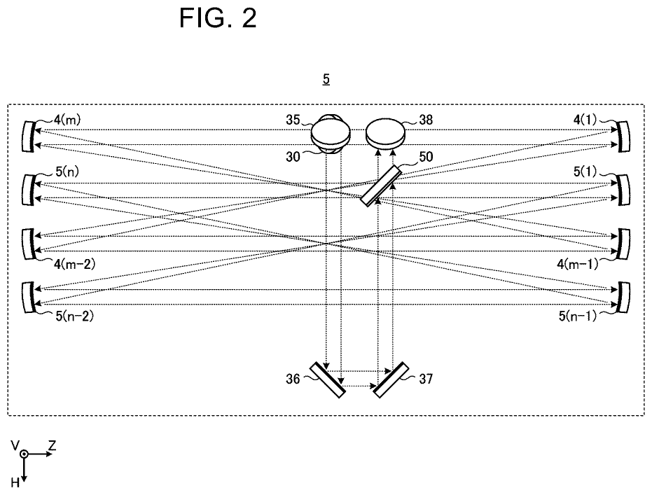

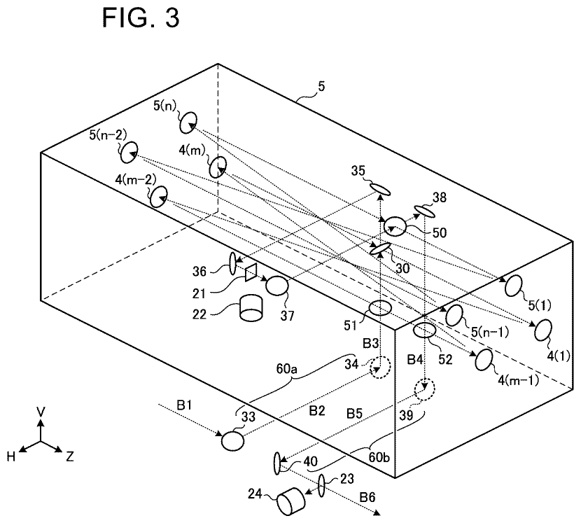

The beam steering device 60a is arranged on the optical path of the laser light B1 output from the output coupling mirror 85, and includes a first input mirror 33 and a second input mirror 34. The pulse extension device 5 is arranged on the optical path of laser light B3 output from the beam steering device 60a. The pulse extension device 5 will be described later with reference to FIGS. 2 and 3. The beam steering device 60b is arranged on the optical path of laser light B4 output from the pulse extension device 5, and includes a first output mirror 39 and a second output mirror 40. The first input mirror 33 and the first output mirror 39 correspond to the first mirror in the present disclosure, and the second input mirror 34 and the second output mirror 40 correspond to the second mirror in the present disclosure.

The pulse extension device 9 is arranged on the optical path of laser light B6 output from the beam steering device 60b. The pulse extension device 9 includes a beam splitter 90 and first to fourth concave mirrors 91 to 94.

### 1.2 Operation of Laser System 100

In the laser oscillator MO, the pulse power source (not shown) generates a pulse high voltage and applies the high voltage between the discharge electrodes 711, 712. When the high voltage is applied between the discharge electrodes 711, 712, discharge occurs between the discharge electrodes 711, 712. The laser gas in the laser chamber 70 is excited by the energy of the discharge and shifts to a high energy level. When the excited laser gas then shifts to a low energy level, light having a wavelength corresponding to the difference between the energy levels is emitted.

The light generated in the laser chamber 70 is output to the outside of the laser chamber 70 through the windows 701, 702. The beam width of the light output through the window 710 is expanded by the prism 741, and then the light is incident on the grating 742. The light incident on the grating 742 from the prism 741 is reflected by a plurality of grooves of the grating 742 and is diffracted in a direction corresponding to the wavelength of the light. The grating 742 is arranged in the Littrow arrangement, which causes the incident angle of the light incident on the grating 742 from the prism 741 to coincide with the diffraction angle of the diffracted light having a desired wavelength. Thus, light having a wavelength close to the desired wavelength returns into the laser chamber 70 via the prism 741.

The output coupling mirror 75 transmits and outputs a part of the light output from the window 702, and reflects the other part back into the laser chamber 70.

In this way, the light output from the laser chamber 70 reciprocates between the line narrowing module 74 and the output coupling mirror 75. This light is amplified every time when passing through a discharge space between the discharge electrodes 711, 712. Further, the light is line-narrowed each time being turned back in the line narrowing module 74. Thus, the light having undergone laser oscillation and line narrowing is output as the laser light B from the output coupling mirror 75.

The laser light B output from the output coupling mirror 75 enters the laser chamber 80 of the laser amplifier PO via the high reflection mirror 761, the high reflection mirror 762, and the rear mirror 84.

In the laser amplifier PO, in synchronization with the entrance of the laser light B into the laser chamber 80, a pulse power source (not shown) generates a pulse high voltage and applies the high voltage between the discharge electrodes 811, 812.

When the high voltage is applied between the discharge electrodes 811, 812, discharge occurs between the discharge electrodes 811, 812. The laser light B having entered the laser chamber 80 is amplified by the energy of the discharge.

The light amplified in the laser chamber 80 reciprocates between the rear mirror 84 and the output coupling mirror 85. This light is amplified every time when passing through a discharge space between the discharge electrodes 811, 812. The amplified laser light B1 is output from the output coupling mirror 85.

The laser light B1 output from the output coupling mirror 85 enters the beam steering device 60a in the Z direction. The laser light B1 is reflected in the −H direction by the first input mirror 33, is reflected in the V direction by the second input mirror 34 as the laser light B3, and is input to the pulse extension device 5. The laser light B4 whose pulse width has been extended by the pulse extension device 5 enters the beam steering device 60b in the −V direction. The laser light B4 is reflected in the H direction by the first output mirror 39, is reflected in the Z direction by the second output mirror 40 as the laser light B6, and enters the pulse extension device 9.

The pulse extension device 9 transmits a part of the laser light B6 that is incident on the beam splitter 90 in the Z direction, outputs the part thereof as a beam Ba, and reflects the other part thereof in the −V direction. The reflected laser light B6 is sequentially reflected by the first to fourth concave mirrors 91 to 94, and is incident on the beam splitter 90 in the −V direction.

The beam cross section of the laser light B6 incident on the beam splitter 90 from the second beam steering device 60b is imaged on the beam splitter 90 with a size of 1:1 owing to the first to fourth concave mirrors 91 to 94. The beam splitter 90 reflects, in the Z direction, a part of the laser light B6 incident thereon in the −V direction from the fourth concave mirror 94 and outputs the part thereof as a beam Bb.

There is a time difference between the beam Ba and the beam Bb according to the optical path length of the delay optical path formed by the first to fourth concave mirrors 91 to 94. By spatially overlapping the beam Ba and the beam Bb, it is possible to output laser light Ba+Bb having an extended pulse width.

### 1.3 Pulse Extension Device 5

FIG. 2 shows the configuration of the pulse extension device 5 of the comparative example viewed in the −V direction. FIG. 3 is a perspective view of the pulse extension device 5 of the comparative example. In FIG. 3, in addition to the pulse extension device 5, the beam steering devices 60a, 60b are also shown. The pulse extension device 5 includes a beam splitter 30, m concave mirrors 4(1) to 4(m), a beam splitter 50, n concave mirrors 5(1) to 5(n), and high reflection mirrors 35 to 38. The signs of parentheses attached to the concave mirrors are natural numbers, and m and n are even numbers, for example. The concave mirrors 4(1) to 4(m) configure a first delay optical path, and the concave mirrors 5(1) to 5(n) configure a second delay optical path.

The laser light B3 reflected in the V direction by the second input mirror 34 is incident on the beam splitter 30 through an opening 51 of a housing accommodating the pulse extension device 5. The beam splitter 30 transmits a part of the laser light B3 toward the high reflection mirror 35, and reflects the other part thereof toward the first delay optical path. In the first delay optical path, the light reflected by the beam splitter 30 is reflected by the concave mirrors 4(1), 4(m-2), 4(m-1), and 4(m) in this order. A part of the light is reflected by the beam splitter 30 toward the high reflection mirror 35.

The laser light B3 incident on the high reflection mirror 35 is incident on the beam splitter 50 via the high reflection mirrors 36, 37. The beam splitter 50 transmits a part of the laser light B3 toward the high reflection mirror 38, and reflects the other part thereof toward the second delay optical path. In the second delay optical path, the light reflected by the beam splitter 50 is reflected by the concave mirrors 5(1), 5(n-2), 5(n-1), and 5(n) in this order. A part of the light is reflected by the beam splitter 50 toward the high reflection mirror 38.

Here, only four concave mirrors 4(1), 4(m-2), 4(m-1), 4(m) are shown as the mirrors configuring the first delay optical path. However, the concave mirrors 4(3), 4(5), and the like (not shown) may be arranged between the concave mirrors 4(1) and 4(m-1), and the concave mirrors 4(2), 4(4), and the like (not shown) of the same number may be arranged between the concave mirrors 4(m-2) and 4(m). In this case, the light is reflected in the order of the concave mirrors 4(1), 4(2), 4(3), 4(4), 4(5), . . . , 4(m-2), 4(m-1), and 4(m). The same applies to the second delay optical path.

The laser light B3 reflected by the high reflection mirror 38 is incident on the first output mirror 39 through the opening 52 of the housing in the −V direction.

### 2. Problem of Comparative Example

By adjusting the orientation of each reflection surface of the first and second input mirrors 33, 34 included in the beam steering device 60a, the beam position and the beam pointing of the laser light B3 can be adjusted. The beam position refers to a position irradiated with the laser light B3 at the measurement position, and the beam pointing refers to a direction in which the laser light B3 travels at the measurement position. A measurement instrument may be arranged on the optical path of the laser light B3, for example, the optical path between the high reflection mirror 35 and the beam splitter 50, and the beam position and the beam pointing of the laser light B3 may be measured. The measurement instrument includes, for example, a glass substrate 21 that emits fluorescence from a portion irradiated with the laser light B3, and an optical sensor 22 that is sensitive to the fluorescence.

Similarly to the beam steering device 60a, by adjusting the orientation of each reflection surface of the first and second output mirrors 39, 40 included in the beam steering device 60b, the beam position and the beam pointing of the laser light B6 can be adjusted. A measurement instrument may be arranged on the optical path of the laser light B6, for example, the optical path between the second output mirror 40 and the beam splitter 90, and the beam position and the beam pointing of the laser light B6 may be measured. The measurement instrument includes, for example, a beam splitter 23 that transmits a part of the laser light B6 and reflects the other part thereof, and an optical sensor 24 arranged on the optical path of the reflection light by the beam splitter 23.

Changing the orientation of the reflection surface of one of the two mirrors included in the beam steering device 60a or 60b always changes the beam pointing. Therefore, when only the beam position is desired to be changed, change in the beam pointing due to adjustment of one mirror has to be canceled out by adjustment of the other mirror. For example, even in a situation in which the beam pointing is excellent but adjustment of the beam position is necessary, it is necessary to temporarily break adjustment of the beam pointing, and it takes time and effort for optical axis adjustment.

Embodiments described below relate to providing a beam steering device and a beam steering method capable of easily and quickly adjusting the beam position and the beam pointing.

### 3. Beam Steering Device in Which Two Mirrors Are Integrally Moved

### 3.1 Beam Steering Device 60c

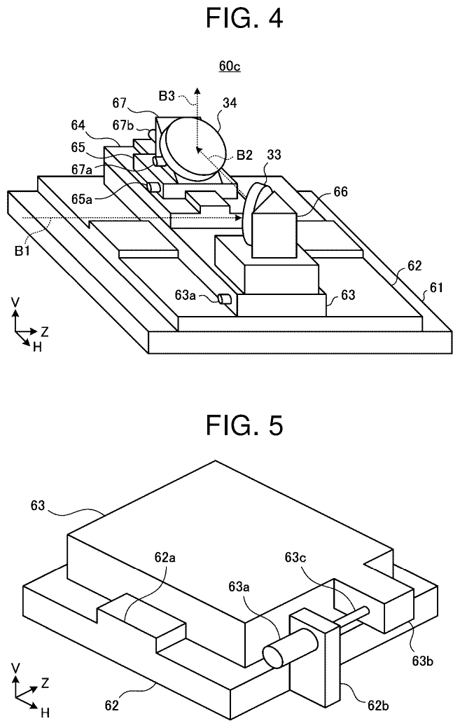

FIG. 4 shows the configuration of a beam steering device 60c according to a first example of a first embodiment. The beam steering device 60c may be used instead of the beam steering device 60a shown in FIGS. 1 and 3.

In addition to the first and second input mirrors 33, 34, the beam steering device 60c includes an installation base 61, a first plate 62, a second plate 63, a third plate 64, a fourth plate 65, and holders 66, 67.

The first input mirror 33 is held by the holder 66, and reflects, in the −H direction as laser light B2, the laser light B1 incident in the Z direction. The holder 66 is fixed to the second plate 63. The incident direction of the laser light B1 incident on the first input mirror 33 is preferably perpendicular to the output direction of the laser light B2 reflected by the first input mirror 33, but may be at an angle other than a right angle thereto.

The second input mirror 34 is held by the holder 67, and reflects, in the V direction as the laser light B3, the laser light B2 reflected by the first input mirror 33. The holder 67 is fixed to the fourth plate 65. The incident direction of the laser light B2 incident on the second input mirror 34 is preferably perpendicular to the output direction of the laser light B3 reflected by the second input mirror 34, but may be at an angle other than a right angle thereto.

The plane of incidence of the laser light B1 with respect to the first input mirror 33, that is, a plane including the optical path axes of both the laser light B1 and the laser light B2, is parallel to an HZ plane. The plane of incidence of the laser light B2 with respect to the second input mirror 34, that is, a plane including the optical path axes of both the laser light B2 and the laser light B3, is parallel to a VH plane. These planes of incidence preferably intersect perpendicularly, but may intersect at an angle other than a right angle.

The first plate 62 is fixed to the installation base 61. A first stage including the first and second plates 62, 63 is a mechanism that moves the second plate 63 with respect to the first plate 62 in a direction parallel to the Z direction, which is the travel direction of the laser light B1, and includes an adjustment knob 63a for adjusting a movement amount thereof. The first stage integrally moves the first input mirror 33 and the second input mirror 34 in the direction parallel to the Z direction. In the present disclosure, the expression “parallel to the travel direction of the laser light” is not limited to a case in which there is no difference in direction, and includes an error within a practical range. For example, the difference in direction may be within 3°.

The third plate 64 is fixed to the second plate 63. A second stage including the third and fourth plates 64, 65 is a mechanism that moves the fourth plate 65 with respect to the third plate 64 in a direction parallel to the −H direction, which is the travel direction of the laser light B2, and includes an adjustment knob 65a for adjusting a movement amount thereof. The second stage moves the second input mirror 34 in the direction parallel to the −H direction.

The holder 67 fixed to the fourth plate 65 includes an adjustment mechanism for adjusting the orientation of the reflection surface of the second input mirror 34. The adjustment mechanism is a mechanism for rotating the orientation of the reflection surface of the second input mirror 34 about two axes, and includes adjustment knobs 67a, 67b for adjusting the rotation angles about the axes. The two axes are, for example, an axis in the Z direction and an axis in the H direction.

The Z direction, the −H direction, and the V direction in the first example of the first embodiment correspond to the first, second, and third directions in the present disclosure, respectively.

FIG. 5 shows the first stage shown in FIG. 4. The first plate 62 included in the first stage includes a rail 62a that restricts the movement direction of the second plate 63 in the direction parallel to the Z direction. The first plate 62 includes a protrusion portion 62b, and a micrometer including the adjustment knob 63a is fixed to the protrusion portion 62b. The micrometer is configured so that the rod 63c can be moved in and out in the Z direction. The second plate 63 is pressed against the first plate 62 in the −Z direction by a spring (not shown).

When the rod 63c moves in the Z direction and presses the protrusion portion 63b of the second plate 63, the second plate 63 moves in the Z direction against the restoring force of the spring (not shown). On the other hand, when the rod 63c moves in the −Z direction, the second plate 63 moves in the −Z direction by the restoring force of the spring (not shown).

The second stage including the third and fourth plates 64, 65 is different from the first stage in that the movement direction is the H direction, but the movement mechanism thereof may be similar to that of the first stage.

In other respects, the beam steering device 60c is similar to the beam steering device 60a.

### 3.2 Beam Steering Device 60d

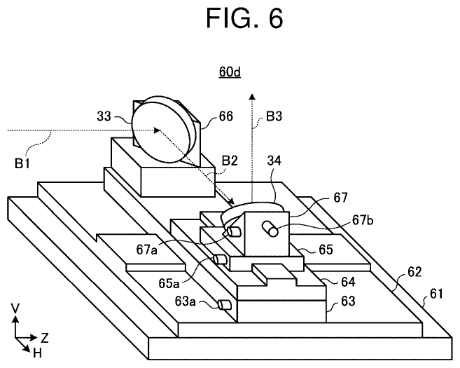

FIG. 6 shows the configuration of a beam steering device 60d according to a second example of the first embodiment. The beam steering device 60d may be used instead of the beam steering device 60c shown in FIG. 4.

The beam steering device 60c and the beam steering device 60d are different from each other in that the positions of the first input mirror 33 and the holder 66 and the positions of the second input mirror 34, the holder 67, the third plate 64, and the fourth plate 65 are interchanged. That is, the first input mirror 33 and the holder 66 are positioned on the −H direction side, and the second input mirror 34, the holder 67, the third plate 64, and the fourth plate 65 are positioned on the H direction side. The first input mirror 33 reflects the laser light B1 in the H direction as the laser light B2.

Here, the position of the adjustment knob 63a in the beam steering device 60d is the same as that in the beam steering device 60c. Therefore, the distance between the adjustment knob 63a and the second input mirror 34 is shorter than the distance between the adjustment knob 63a and the first input mirror 33.

The Z direction, the H direction, and the V direction in the second example of the first embodiment correspond to the first, second, and third directions in the present disclosure, respectively.

In other respects, the beam steering device 60d is similar to the beam steering device 60c.

### 3.3 Beam Steering Device 60e

FIG. 7 shows the configuration of a beam steering device 60e according to a third example of the first embodiment. The beam steering device 60e may be used instead of the beam steering device 60b shown in FIGS. 1 and 3.

In addition to the first and second output mirrors 39, 40, the beam steering device 60e includes the installation base 61, a first plate 68, a second plate 69, the third plate 64, the fourth plate 65, and the holders 66, 67.

The first output mirror 39 is held by the holder 66, and reflects, in the H direction as laser light B5, the laser light B4 incident in the −V direction. The holder 66 is fixed to the second plate 69. The incident direction of the laser light B4 incident on the first output mirror 39 is preferably perpendicular to the output direction of the laser light B5 reflected by the first output mirror 39, but may be at an angle other than a right angle thereto.

The second output mirror 40 is held by the holder 67, and reflects, in the Z direction as the laser light B6, the laser light B5 reflected by the first output mirror 39. The holder 67 is fixed to the fourth plate 65. The incident direction of the laser light B5 incident on the second output mirror 40 is preferably perpendicular to the output direction of the laser light B6 reflected by the second output mirror 40, but may be at an angle other than a right angle thereto.

The plane of incidence of the laser light B4 with respect to the first output mirror 39, that is, a plane including the optical path axes of both the laser light B4 and the laser light B5, is parallel to the VH plane. The plane of incidence of the laser light B5 with respect to the second output mirror 40, that is, a plane including the optical path axes of both the laser light B5 and the laser light B6, is parallel to the HZ plane. These planes of incidence preferably intersect perpendicularly, but may intersect at an angle other than a right angle.

The first plate 68 is fixed to the installation base 61. The first stage including the first and second plates 68, 69 is a mechanism that moves the second plate 69 with respect to the first plate 68 in a direction parallel to the −V direction, which is the travel direction of the laser light B4, and includes an adjustment knob 68a for adjusting a movement amount thereof. The first stage integrally moves the first output mirror 39 and the second output mirror 40 in the direction parallel to the −V direction.

The third plate 64 is fixed to the second plate 69. The second stage including the third and fourth plates 64, 65 is a mechanism that moves the fourth plate 65 with respect to the third plate 64 in a direction parallel to the H direction, which is the travel direction of the laser light B5, and includes an adjustment knob 65a for adjusting a movement amount thereof. The second stage moves the second output mirror 40 in the direction parallel to the H direction.

The holder 67 fixed to the fourth plate 65 includes an adjustment mechanism for adjusting the orientation of the reflection surface of the second output mirror 40. The adjustment mechanism is a mechanism for rotating the orientation of the reflection surface of the second output mirror 40 about two axes, and includes adjustment knobs 67a, 67b for adjusting the rotation angles about the axes. The two axes are, for example, an axis in the Z direction and an axis in the H direction.

The −V direction, the H direction, and the Z direction in the third example of the first embodiment correspond to the first, second, and third directions in the present disclosure, respectively.

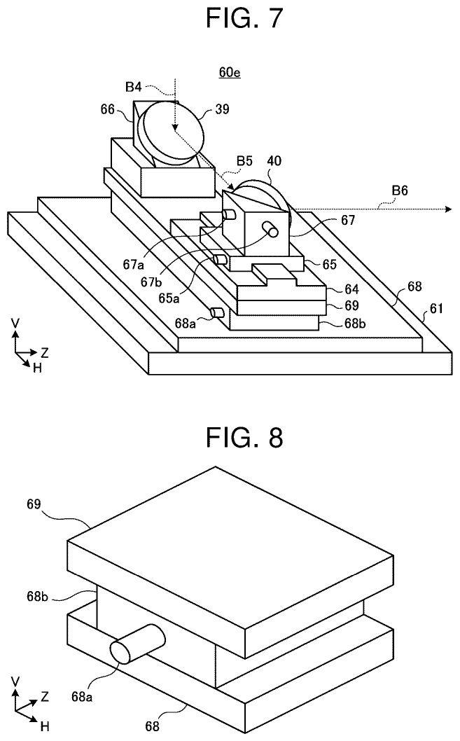

FIG. 8 shows the first stage shown in FIG. 7. The first plate 68 included in the first stage includes a movement mechanism 68b that moves the second plate 69 in the direction parallel to the −V direction.

In other respects, the beam steering device 60e is similar to the beam steering device 60b.

Alternatively, in the first embodiment, a combination of the beam steering device 60c of the first example and the beam steering device 60e of the third example may be used. Further, a combination of the beam steering device 60d of the second example and the beam steering device 60e of the third example may be used. In this case, the beam steering device 60e, the first output mirror 39, the second output mirror 40, and the holder 67 may be referred to as an output beam steering device, a third mirror, a fourth mirror, and an output mirror holder, respectively. The stage including the first and second plates 68, 69 may be referred to as a third stage, and the stage including the third and fourth plates 64, 65 may be referred to as a fourth stage. Further, the −V direction, the H direction, and the Z direction in the third example may be referred to as the fourth, fifth, and sixth directions, respectively. The third direction (V direction) in the first example and the fourth direction (−V direction) in the third example are opposite directions, the second direction (−H direction) in the first example and the fifth direction (H direction) in the third example are parallel directions, and the first direction (Z direction) in the first example and the sixth direction (Z direction) in the third example are the same direction. The second direction (H direction) in the second example and the fifth direction (H direction) in the third example are the same direction.

Alternatively, as in the second example with respect to the first example, in the third example, the positions of the first output mirror 39 and the holder 66 and the positions of the second output mirror 40, the holder 67, the third plate 64, and the fourth plate 65 may be interchanged.

### 3.4 Effect

(1) According to the first example of the first embodiment, the beam steering device 60c includes the first input mirror 33, the second input mirror 34, the first stage including the first plate 62 and the second plate 63, the second stage including the third plate 64 and the fourth plate 65, and the holder 67. The first input mirror 33 reflects, in the −H direction, the laser light B1 incident in the Z direction. The second input mirror 34 reflects, in the V direction, the laser light B2 reflected by the first input mirror 33. The first stage integrally moves the first input mirror 33 and the second input mirror 34 in the direction parallel to the Z direction. The second stage is arranged on the first stage and moves the second input mirror 34 in the direction parallel to the −H direction. The holder 67 is arranged on the second stage and adjusts the orientation of the reflection surface of the second input mirror 34.

According to the above, since the first and second input mirrors 33, 34 are moved integrally in the direction parallel to the Z direction, the beam position can be changed while suppressing the change in the beam pointing, and the first and second input mirrors 33, 34 are suppressed from being deviated from the optical path of the laser light B1. Further, since the second input mirror 34 is moved in the direction parallel to the −H direction, the beam position can be changed while suppressing the change in the beam pointing, and the second input mirror 34 is suppressed from being deviated from the optical path of the laser light B2. Further, by adjusting the orientation of the reflection surface of the second input mirror 34, the beam pointing can be adjusted while suppressing the change in the beam position. Therefore, since adjustment of the beam position and adjustment of the beam pointing can be performed independently, optical axis adjustment can be facilitated. Further, since the first stage moves the first input mirror 33 and the second input mirror 34 integrally, the movement direction and the movement amount can be easily matched.
(2) According to the first embodiment, the first input mirror 33 and the second input mirror 34 are arranged such that the plane of incidence of the laser light B1 with respect to the first input mirror 33 intersects the plane of incidence of the laser light B2 with respect to the second input mirror 34.

According to the above, the beam position of the laser light B3 can be adjusted in two axes.
(3) According to the first embodiment, the first input mirror 33 and the second input mirror 34 are arranged such that the plane of incidence of the laser light B1 with respect to the first input mirror 33 perpendicularly intersects the plane of incidence of the laser light B2 with respect to the second input mirror 34.

According to the above, the beam position of the laser light B3 can be adjusted in two axes perpendicular to each other.
(4) According to the first embodiment, the first input mirror 33 is arranged such that the incident direction of the laser light B1 and the output direction of the laser light B2 are perpendicular to each other.

According to the above, the beam position of the laser light B3 can be largely moved when the first input mirror 33 is moved.
(5) According to the first embodiment, the second input mirror 34 is arranged such that the incident direction of the laser light B2 and the output direction of the laser light B3 are perpendicular to each other.

According to the above, the beam position of the laser light B3 can be largely moved when the second input mirror 34 is moved. Further, by combinations of (3) to (5), the plane perpendicular to the incident direction of the laser light B1 and the plane perpendicular to the output direction of the laser light B3 are perpendicular to each other, so that the optical path design in the laser system 100 can be facilitated.
(6) According to the second example of the first embodiment, the first stage includes the adjustment knob 63a for adjusting the movement amount of the first input mirror 33 and the second input mirror 34, and the distance between the adjustment knob 63a and the second input mirror 34 is shorter than the distance between the adjustment knob 63a and the first input mirror 33.

According to the above, the adjustment knob 63a of the first stage can be arranged at a position close to the adjustment knob 65a of the second stage and the adjustment knobs 67a, 67b for adjusting the rotation angle of the holder 67, so that optical axis adjustment can be facilitated.
(7) According to the first example of the first embodiment, the laser system 100 includes the laser oscillator MO, the pulse extension device 5 including the delay optical path formed by the concave mirrors 4(1) to 4(m) and 5(1) to 5(n), and the beam steering device 60c. The delay optical path allows a part of the laser light B3 output from the laser oscillator MO to pass therethrough. The beam steering device 60c is arranged on the optical path of the laser light B1 between the laser oscillator MO and the pulse extension device 5.

According to the above, by adjusting the optical axis of the laser light B3 prior to being input to the pulse extension device 5 having a long optical path length of the delay optical path, it is possible to suppress optical path deviation in the pulse extension device 5.
(8) According to the first embodiment, the laser system 100 includes the measurement instrument including the optical sensor 22 arranged on the optical path of the laser light B3 inside the pulse extension device 5 and configured to measure the beam position and the beam pointing of the laser light B3.

According to the above, the beam position and the beam pointing can be adjusted based on the measurement result of the measurement instrument, and the accuracy of adjustment can be improved.
(9) According to the combination of the first example and the third example of the first embodiment, the laser system 100 includes, in addition to the beam steering device 60c, the beam steering device 60e arranged on the optical path of the laser light B4 output from the pulse extension device 5. The beam steering device 60e includes the first output mirror 39, the second output mirror 40, the third stage including the first plate 68 and the second plate 69, the fourth stage including the third plate 64 and the fourth plate 65, and the holder 67. The first output mirror 39 reflects, in the H direction, the laser light B4 incident in the −V direction. The second output mirror 40 reflects, in the Z direction, the laser light B5 reflected by the first output mirror 39. The third stage integrally moves the first output mirror 39 and the second output mirror 40 in the direction parallel to the −V direction. The fourth stage is arranged on the third stage and moves the second output mirror 40 in the direction parallel to the H direction. The holder 67 is arranged on the fourth stage and adjusts the orientation of the reflection surface of the second output mirror 40.

According to the above, by adjusting the optical axis of the laser light B4 output from the pulse extension device 5, it is possible to suppress optical path deviation in an optical device subsequent to the pulse extension device 5.
(10) According to the first embodiment, the laser system 100 includes the measurement instrument including the optical sensor 24 arranged on the optical path of the laser light B6 reflected by the second output mirror 40 and configured to measure the beam position and the beam pointing of the laser light B6.

According to the above, the beam position and the beam pointing can be adjusted based on the measurement result of the measurement instrument, and the accuracy of adjustment can be improved.
(11) According to the combination of the first example and the third example of the first embodiment, the output direction (V direction) of the laser light B3 and the incident direction (−V direction) of the laser light B4 are opposite directions, the output direction (−H direction) of the laser light B2 and the output direction (H direction) of the laser light B5 are parallel directions, and the incident direction (Z direction) of the laser light B1 and the output direction (Z direction) of the laser light B6 are the same direction.

According to the above, since the laser light B6 is output in the same direction as the incident direction (Z direction) of the laser light B1 toward the optical device subsequent to the pulse extension device 5, the laser system 100 can be compactly arranged even if the pulse extension device 5 having a long delay optical path length is provided.
(12) According to the combination of the second example and the third example of the first embodiment, the output direction (V direction) of the laser light B3 and the incident direction (−V direction) of the laser light B4 are opposite directions, the output direction (H direction) of the laser light B2 and the output direction (H direction) of the laser light B5 are the same direction, and the incident direction (Z direction) of the laser light B1 and the output direction (Z direction) of the laser light B6 are the same direction.

According to the above, since the output direction of the laser light B2 and the output direction of the laser light B5 are the same H direction, the second input mirror 34 and the second output mirror 40 can be arranged close to a maintenance surface that is easily accessible from the outside of the laser system 100.

In other respects, the first embodiment is similar to the comparative example.

### 4. Beam Steering Method

4.1 Main flow

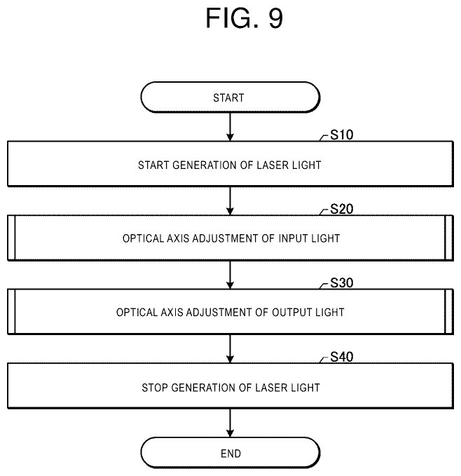

FIG. 9 is a flowchart of optical axis adjustment in a second embodiment. In the second embodiment, the configuration of the beam steering device may be similar to that of the first embodiment. Although a case in which an operator performs the following procedure will be described, the following procedure may be performed by a processor (not shown) if the beam steering device 60c, 60d, or 60e includes actuators (not shown) for adjusting the positions of the mirrors and the orientations of the reflection surfaces.

In S10, the laser oscillator MO and the laser amplifier PO are activated, and generation of the laser light B1 is started.

In S20, optical axis adjustment of input light is performed by adjusting the beam steering device 60c based on the measurement result from the measurement instrument including the optical sensor 22. The beam steering device 60d may be used instead of the beam steering device 60c.

In S30, optical axis adjustment of output light is performed by adjusting the beam steering device 60e based on the measurement result from the measurement instrument including the optical sensor 24.

In S40, a part of operation of the laser oscillator MO and the laser amplifier PO is stopped, and generation of the laser light B1 is stopped. After S40, operation of the present flowchart is ended.

### 4.2 First Example of Optical Axis Adjustment of Input Light

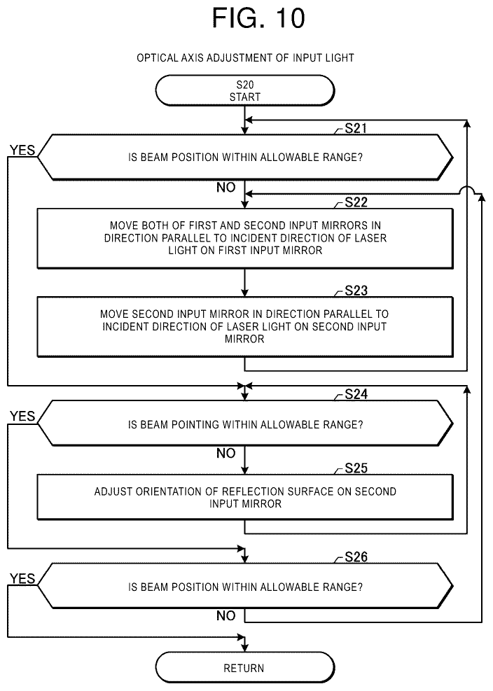

FIG. 10 is a flowchart of a first example of optical axis adjustment of input light in the second embodiment. The procedure shown in FIG. 10 corresponds to a subroutine of S20 of FIG. 9.

In S21, it is determined whether or not the beam position is within an allowable range. When the beam position is not within the allowable range (S21: NO), processing proceeds to S22.

In S22, the first stage is adjusted, and both the first and second input mirrors 33, 34 are moved by the same amount in the direction parallel to the Z direction so that the beam position approaches a target value thereof. At this time, the current orientation of each reflection surface of the first and second input mirrors 33, 34 is maintained.

In S23, the second stage is adjusted, and the second input mirror 34 is moved in the direction parallel to the −H direction so that the beam position approaches the target value thereof. At this time, the current orientation of each reflection surface of the first and second input mirrors 33, 34 is maintained. After S23, processing returns to S21.

When the beam position is within the allowable range in S21 (S21: YES), processing proceeds to S24.

In S24, it is determined whether or not the beam pointing is within an allowable range. When the beam pointing is not within the allowable range (S24: NO), processing proceeds to S25.

In S25, the holder 67 is adjusted to change the orientation of the reflection surface of the second input mirror 34 so that the beam pointing approaches a target value thereof. At this time, the positions of the holders 66, 67 holding the first and second input mirrors 33, 34, respectively, are maintained. After S25, processing returns to S24.

When the beam pointing is within the allowable range in S24 (S24: YES), operation of the present flowchart may be ended and processing may return to operation shown in FIG. 9. However, since the beam position may be deviated when the beam pointing is greatly adjusted, operation of S26 may be performed.

In S26, it is determined whether or not the beam position is within the allowable range. When the beam position is not within the allowable range (S26: NO), processing returns to S22. When the beam position is within the allowable range (S26: YES), operation of the present flowchart is ended and processing returns to operation shown in FIG. 9.

### 4.3 First Example of Optical Axis Adjustment of Output Light

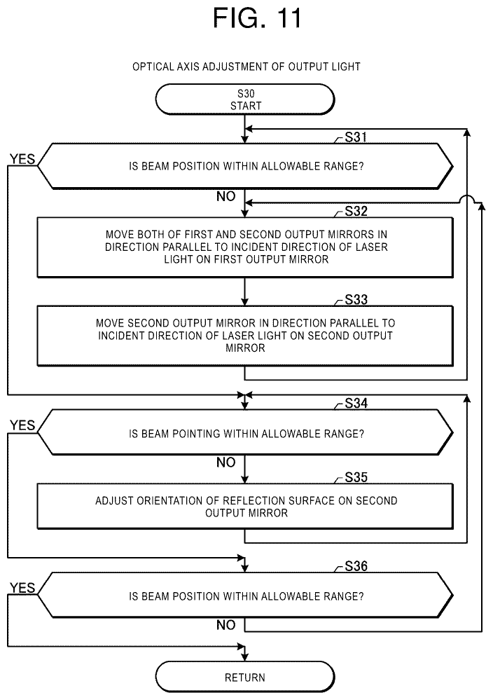

FIG. 11 is a flowchart of a first example of optical axis adjustment of the output light in the second embodiment. The procedure shown in FIG. 11 corresponds to a subroutine of S30 of FIG. 9.

In S31, it is determined whether or not the beam position is within the allowable range. When the beam position is not within the allowable range (S31: NO), processing proceeds to S32.

In S32, the first stage is adjusted, and both the first and second output mirrors 39, 40 are moved by the same amount in the direction parallel to the −V direction so that the beam position approaches the target value thereof. At this time, the current orientation of each reflection surface of the first and second output mirrors 39, 40 is maintained.

In S33, the second stage is adjusted, and the second output mirror 40 is moved in the direction parallel to the H direction so that the beam position approaches the target value thereof. At this time, the current orientation of each reflection surface of the first and second output mirrors 39, 40 is maintained. After S33, processing returns to S31.

When the beam position is within the allowable range in S31 (S31: YES), processing proceeds to S34.

In S34, it is determined whether or not the beam pointing is within the allowable range. When the beam pointing is not within the allowable range (S34: NO), processing proceeds to S35.

In S35, the holder 67 is adjusted to change the orientation of the reflection surface of the second output mirror 40 so that the beam pointing approaches the target value thereof. At this time, the positions of the holders 66, 67 holding the first and second output mirrors 39, 40, respectively, are maintained. After S35, processing returns to S34.

When the beam pointing is within the allowable range in S34 (S34: YES), operation of the present flowchart may be ended and processing may return to operation shown in FIG. 9. However, since the beam position may be deviated when the beam pointing is greatly adjusted, operation of S36 may be performed.

In S36, it is determined whether or not the beam position is within the allowable range. When the beam position is not within the allowable range (S36: NO), processing returns to S32. When the beam position is within the allowable range (S36: YES), operation of the present flowchart is ended and processing returns to operation shown in FIG. 9.

### 4.4 Second Example of Optical Axis Adjustment of Input Light

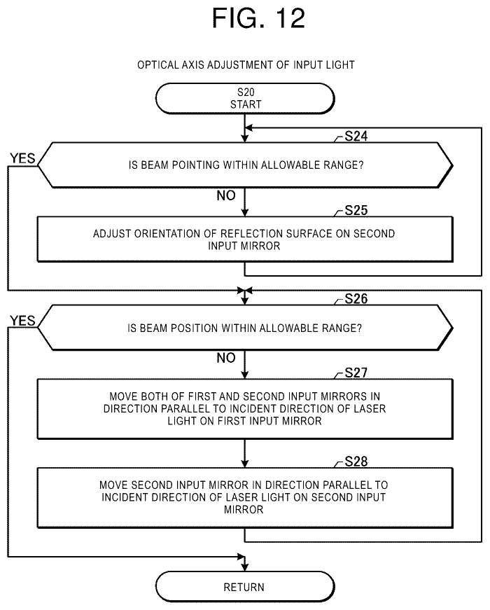

FIG. 12 is a flowchart of a second example of optical axis adjustment of the input light in the second embodiment. The procedure shown in FIG. 12 corresponds to a subroutine of S20 of FIG. 9. Procedures of S21 to S23 included in the first example shown in FIG. 10 are not performed in FIG. 12, and procedures of S27 and S28 are performed instead. S24 and S25 are similar to those in FIG. 10. Procedures of S27 and S28 are similar to those of S22 and S23, respectively.

Accordingly, the beam pointing is adjusted first, and then the beam position is adjusted.

### 4.5 Second Example of Optical Axis Adjustment of Output Light

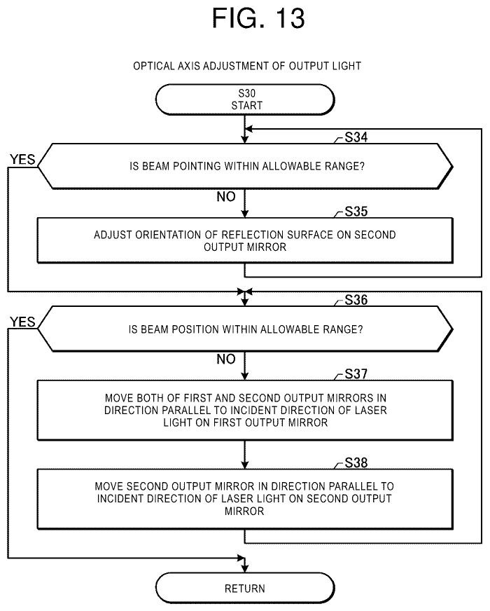

FIG. 13 is a flowchart of a second example of optical axis adjustment of the output light in the second embodiment. The procedure shown in FIG. 13 corresponds to a subroutine of S30 of FIG. 9. Procedures of S31 to S33 included in the first example shown in FIG. 11 are not performed in FIG. 13, and procedures of S37 and S38 are performed instead. S34 and S35 are similar to those in FIG. 11. Procedures of S37 and S38 are similar to those of S32 and S33, respectively.

Accordingly, the beam pointing is adjusted first, and then the beam position is adjusted.

In other respects, the second embodiment is similar to the first embodiment.

### 4.6 Effect

(13) According to the second embodiment, the beam steering method is a beam steering method for the laser light B1 using the beam steering device 60c including the first input mirror 33 that reflects, in the −H direction, the laser light B1 incident in the Z direction, and the second input mirror 34 that reflects, in the V direction, the laser light B2 reflected by the first input mirror 33. The beam steering method includes moving the first input mirror 33 and the second input mirror 34 by the same amount in the direction parallel to the Z direction (S22), moving the second input mirror 34 in the direction parallel to the −H direction (S23), and adjusting the orientation of the reflection surface of the second input mirror 34 (S25).

Here, moving by the same amount means moving in the same direction as well as having the same absolute value of the movement amount.

According to the above, since adjustment of the beam position and adjustment of the beam pointing can be performed independently, optical axis adjustment can be facilitated.
(14) In the second embodiment, the first input mirror 33 and the second input mirror 34 are integrally moved in the direction parallel to the Z direction, so that the first input mirror 33 and the second input mirror 34 are moved by the same amount.

According to the above, since the first input mirror 33 and the second input mirror 34 are moved integrally, the movement direction and the movement amount can be easily matched.
(15) According to the second embodiment, the first input mirror 33 reflects the laser light B1 so that the incident direction of the laser light B1 and the output direction of the laser light B2 are perpendicular to each other.

According to the above, the beam position of the laser light B3 can be largely moved when the first input mirror 33 is moved.
(16) According to the second embodiment, the second input mirror 34 reflects the laser light B2 so that the incident direction of the laser light B2 and the output direction of the laser light B3 are perpendicular to each other.

According to the above, the beam position of the laser light B3 can be largely moved when the second input mirror 34 is moved.
(17) According to the second embodiment, the orientation of each reflection surface of the first input mirror 33 and the second input mirror 34 is maintained during the moving of the first input mirror 33 and the second input mirror 34 in the direction parallel to the Z direction (S22) and during the moving of the second input mirror 34 in the direction parallel to the −H direction (S23).

According to the above, since the orientation of each reflection surface of the first input mirror 33 and the second input mirror 34 is maintained, operation of optical axis adjustment by the mirror movement can be simplified.
(18) According to the second embodiment, the position of the holder 67 holding the second input mirror 34 is maintained during the adjusting of the orientation of the reflection surface of the second input mirror 34 (S25).

According to the above, the position of the second input mirror 34 is suppressed from being deviated, so that operation of optical axis adjustment by changing the orientation of each reflection surface of the mirrors can be simplified.
(19) According to the second example of the second embodiment, the moving of the first input mirror 33 and the second input mirror in the direction parallel to the Z direction by the same amount (S27) and the moving of the second input mirror 34 in the direction parallel to the −H direction (S28) are performed after performing the adjusting of the orientation of the reflection surface of the second input mirror 34 (S25).

Although beam position deviation due to adjustment of the beam pointing may occur only slightly, beam pointing deviation due to adjustment of the beam position is even smaller. Therefore, adjusting the beam position after adjusting the beam pointing reduces the necessity of further adjustment of the beam pointing thereafter.

In other respects, the second embodiment is similar to the first embodiment.

### 5. Others

### 5.1 Electronic Device Manufacturing Method

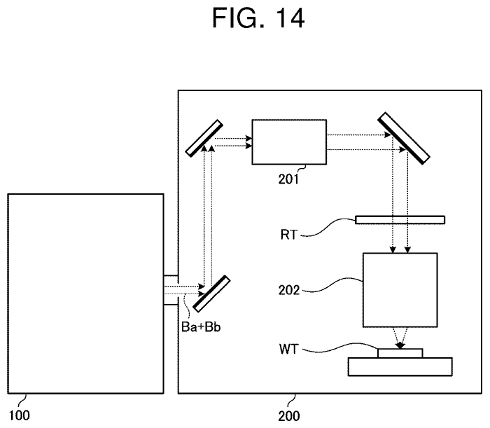

FIG. 14 shows the configuration of an exposure system. The exposure system includes the laser system 100 and an exposure apparatus 200. The laser system 100 is configured to output the laser light Ba+Bb toward the exposure apparatus 200.

The exposure apparatus 200 includes an illumination optical system 201 and a projection optical system 202. The illumination optical system 201 illuminates a reticle pattern of a reticle (not shown) arranged on a reticle stage RT with the laser light Ba+Bb incident from the laser system 100. The projection optical system 202 causes the laser light Ba+Bb transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the laser light Ba+Bb reflecting the reticle pattern. After the reticle pattern is transferred onto the semiconductor wafer by the exposure process described above, an electronic device can be manufactured through a plurality of processes.

### 5.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A beam steering device comprising:
a first mirror configured to reflect, in a second direction, laser light incident thereon in a first direction;
a second mirror configured to reflect, in a third direction, the laser light reflected by the first mirror;
a first stage configured to integrally move the first mirror and the second mirror in a direction parallel to the first direction;
a second stage arranged on the first stage and configured to move the second mirror in a direction parallel to the second direction; and
a holder arranged on the second stage and configured to adjust an orientation of a reflection surface of the second mirror.

2. The beam steering device according to claim 1,
wherein the first mirror and the second mirror are arranged such that a plane of incidence of the laser light with respect to the first mirror intersects a plane of incidence of the laser light with respect to the second mirror.

3. The beam steering device according to claim 1,
wherein the first mirror and the second mirror are arranged such that a plane of incidence of the laser light with respect to the first mirror perpendicularly intersects a plane of incidence of the laser light with respect to the second mirror.

4. The beam steering device according to claim 1,
wherein the first mirror is arranged such that the first direction and the second direction are perpendicular to each other.

5. The beam steering device according to claim 1,
wherein the second mirror is arranged such that the second direction and the third direction are perpendicular to each other.

6. The beam steering device according to claim 1,
wherein the first stage includes an adjustment knob for adjusting a movement amount of the first mirror and the second mirror, and a distance between the adjustment knob and the second mirror is shorter than a distance between the adjustment knob and the first mirror.

7. A laser system comprising:
a laser oscillator;
a pulse extension device including a delay optical path that allows a portion of the laser light output from the laser oscillator to pass therethrough; and
the beam steering device according to claim 1 arranged on an optical path of the laser light between the laser oscillator and the pulse extension device.

8. The laser system according to claim 7,
further comprising a measurement instrument arranged on an optical path of the laser light inside the pulse extension device and configured to measure a beam position and a beam pointing of the laser light.

9. The laser system according to claim 7,
further comprising an output beam steering device arranged on an optical path of the laser light output from the pulse extension device,
the output beam steering device including:
a third mirror configured to reflect, in a fifth direction, the laser light incident thereon in a fourth direction;
a fourth mirror configured to reflect, in a sixth direction, the laser light reflected by the third mirror;
a third stage configured to integrally move the third mirror and the fourth mirror in a direction parallel to the fourth direction;
a fourth stage arranged on the third stage and configured to move the fourth mirror in a direction parallel to the fifth direction; and
an output mirror holder arranged on the fourth stage and configured to adjust an orientation of a reflection surface of the fourth mirror.

10. The laser system according to claim 9,
further comprising a measurement instrument arranged on an optical path of the laser light reflected by the fourth mirror and configured to measure a beam position and a beam pointing of the laser light.

11. The laser system according to claim 9,
wherein the third direction and the fourth direction are opposite directions,
the second direction and the fifth direction are parallel directions, and
the first direction and the sixth direction are the same direction.

12. The laser system according to claim 9,
wherein the third direction and the fourth direction are opposite directions,
the second direction and the fifth direction are the same direction, and
the first direction and the sixth direction are the same direction.

13. A beam steering method using a beam steering device for laser light, comprising:
moving a first mirror and a second mirror in a direction parallel to a first direction by a same amount;
moving the second mirror in a direction parallel to a second direction; and
adjusting an orientation of a reflection surface of the second mirror,
the beam steering device including:
the first mirror configured to reflect, in the second direction, the laser light incident thereon in the first direction; and
the second mirror configured to reflect, in a third direction, the laser light reflected by the first mirror.

14. The beam steering method according to claim 13,
wherein the moving of the first mirror and the second mirror by the same amount is performed by integrally moving the first mirror and the second mirror in the direction parallel to the first direction.

15. The beam steering method according to claim 13,
wherein the first mirror reflects the laser light such that the first direction and the second direction are perpendicular to each other.

16. The beam steering method according to claim 13,
wherein the second mirror reflects the laser light such that the second direction and the third direction are perpendicular to each other.

17. The beam steering method according to claim 13,
wherein orientations of a reflection surface of the first mirror and the reflection surface of the second mirror are maintained during the moving of the first mirror and the second mirror in the direction parallel to the first direction and during the moving of the second mirror in the direction parallel to the second direction.

18. The beam steering method according to claim 13,
wherein a position of a holder holding the second mirror is maintained during the adjusting of the orientation of the reflection surface of the second mirror.

19. The beam steering method according to claim 13,
wherein the moving of the first mirror and the second mirror in the direction parallel to the first direction by the same amount and the moving of the second mirror in the direction parallel to the second direction are performed after performing the adjusting of the orientation of the reflection surface of the second mirror.

20. An electronic device manufacturing method, comprising:
generating laser light using a laser system;
outputting the laser light to an exposure apparatus; and
exposing a photosensitive substrate to the laser light in the exposure apparatus to manufacture an electronic device,
the laser system including:
a laser oscillator;
a pulse extension device including a delay optical path that allows a portion of the laser light output from the laser oscillator to pass therethrough; and
a beam steering device arranged on an optical path of the laser light between the laser oscillator and the pulse extension device, and
the beam steering device including:
a first mirror configured to reflect, in a second direction, the laser light incident thereon in a first direction;
a second mirror configured to reflect, in a third direction, the laser light reflected by the first mirror;
a first stage configured to integrally move the first mirror and the second mirror in a direction parallel to the first direction;
a second stage arranged on the first stage and configured to move the second mirror in a direction parallel to the second direction; and
a holder arranged on the second stage and configured to adjust an orientation of a reflection surface of the second mirror.
